(19) United States
(12) Patent Application Publication
(10) Pub. No.: US 2022/0189801 A1
(43) Pub. Date: Jun. 16, 2022

(54) SUBSTRATE PROCESSING APPARATUS, METHOD OF MANUFACTURING SEMICONDUCTOR DEVICE, AND NON-TRANSITORY COMPUTER-READABLE RECORDING MEDIUM

(71) Applicant: KOKUSAI ELECTRIC CORPORATION, Tokyo (JP)

(72) Inventors: Hidehiro YANAI, Toyama-shi (JP); Shigenori TEZUKA, Toyama-shi (JP)

(73) Assignee: KOKUSAI ELECTRIC CORPORATION, Tokyo (JP)

(21) Appl. No.: 17/687,046

(22) Filed: Mar. 4, 2022

Related U.S. Application Data
(63) Continuation of application No. PCT/JP2019/034992, filed on Sep. 5, 2019.

(51) Int. Cl. H01L 21/67; H01L 21/677

(52) U.S. Cl. CPC H01L 21/67184; H01L 21/67736; H01L 21/67248; H01L 21/67196

(57) ABSTRACT

There is provided a technique including a plurality of process chambers to process a substrate; a plurality of standby chambers to accommodate the substrate; a transfer chamber disposed adjacent to the plurality of standby chambers and the plurality of process chambers; a transfer robot in the transfer chamber to transfer the substrate between one of the plurality of process chambers and one of the plurality of standby chambers or between the plurality of standby chambers adjacent to each other across the transfer chamber; a temperature adjustment mechanism to adjust temperature of at least one of the plurality of standby chambers; and a controller capable of controlling the temperature adjustment mechanism to change a mode of temperature adjustment of the at least one of the plurality of standby chambers depending on a transfer path through which the substrate accommodated in the at least one of the plurality of standby chambers passes.

### CROSS-REFERENCE TO RELATED APPLICATION

This application is a Bypass Continuation Application of PCT International Application No. PCT/JP2019/034992, filed on Sep. 5, 2019, the disclosure of which is incorporated herein in its entirety by reference.

### BACKGROUND

### Field

The present disclosure relates to a substrate processing apparatus, a method of manufacturing a semiconductor device, and a non-transitory computer-readable recording medium.

### Description of the Related Art

When a substrate processing is performed in a substrate processing apparatus used in a manufacturing step of a semiconductor device, processing of improving work efficiency such as simultaneously loading substrates into a plurality of process chambers may be performed.

### SUMMARY

An object of the present disclosure is to further improve work efficiency in a substrate processing.

According to an embodiment, there is provided a technique including:

a plurality of process chambers configured to process a substrate;

a plurality of standby chambers configured to accommodate the substrate;

a transfer chamber disposed adjacent to the plurality of standby chambers and the plurality of process chambers;

a transfer robot provided in the transfer chamber and configured to transfer the substrate between one of the plurality of process chambers and one of the plurality of standby chambers or between the plurality of standby chambers adjacent to each other across the transfer chamber;

a temperature adjustment mechanism configured to adjust temperature of at least one of the plurality of standby chamber; and

a controller configured to be capable of controlling the temperature adjustment mechanism so as to change a mode of temperature adjustment of the at least one of the plurality of standby chambers depending on a transfer path through which the substrate accommodated in the at least one of the plurality of standby chambers passes.

### BRIEF DESCRIPTION OF THE DRAWINGS

FIG. 1 is a schematic configuration view of a substrate processing apparatus according to an embodiment of the present disclosure.

FIG. 2 is a side cross-sectional view that schematically illustrates a schematic configuration example of a process chamber included in the substrate processing apparatus according to the embodiment of the present disclosure.

FIG. 3 is a block diagram that schematically illustrates a configuration example of a controller included in the substrate processing apparatus according to the embodiment of the present disclosure.

FIG. 4 is a flowchart that illustrates a process of film forming performed by the substrate processing apparatus according to the embodiment of the present disclosure.

FIGS. 5A and 5B are diagrams that illustrate a transfer example in which an unprocessed substrate is transferred from a standby chamber to a process chamber in the substrate processing apparatus according to the embodiment of the present disclosure.

FIGS. 6A and 6B are diagrams that illustrate a transfer example in which a processed substrate is unloaded from the process chamber and an unprocessed substrate is loaded into the process chamber in the substrate processing apparatus according to the embodiment of the present disclosure.

FIGS. 7A and 7B are diagrams that illustrate a transfer example in which a processed substrate is transferred from the process chamber to the standby chamber in the substrate processing apparatus according to the embodiment of the present disclosure.

### DETAILED DESCRIPTION

### An Embodiment of the Present Disclosure

An embodiment of the present disclosure will be described below with reference to the drawings.

### (1) Configuration Example of Substrate Processing Apparatus

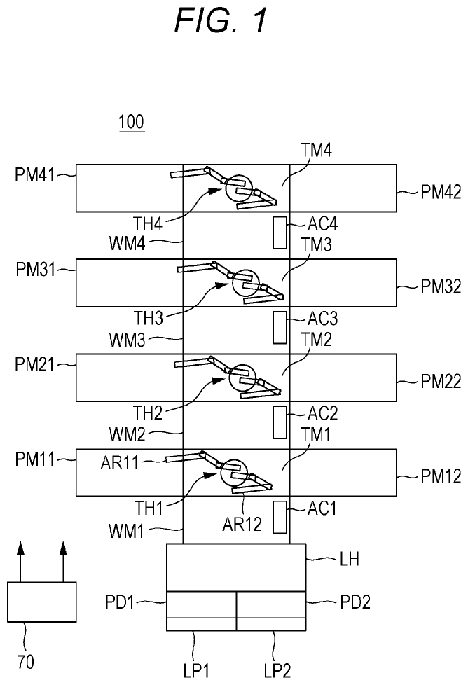

A schematic configuration example of a substrate processing apparatus 100 of the present disclosure will be described with reference to FIG. 1.

### Overall Configuration

The substrate processing apparatus 100 of the present disclosure mainly includes first to fourth process chambers PM11 to PM42 that process substrates, first to fourth transfer chambers TM1 to TM4 that include first to fourth transfer robots TH1 to TH4 that transfer substrates, first to fourth standby chambers WM1 to WM4 that couple between the first to fourth transfer chambers TM1 to TM4 that are adjacent to each other, first to fourth temperature adjustment mechanisms AC1 to AC4 that are included in the first to fourth standby chambers WM1 to WM4, an atmospheric transfer chamber LH that is adjacent to the first standby chamber WM1, and load ports LP1 and LP2 that are adjacent to the atmospheric transfer chamber LH.

The first to fourth transfer chambers TM1 to TM4 and the first to fourth standby chambers WM1 to WM4 are alternately arranged so as to be adjacent to each other. Specifically, the first transfer chamber TM1 is adjacent to the atmospheric transfer chamber LH via the first standby chamber WM1. The second transfer chamber TM2 is adjacent to the first transfer chamber TM1 via the second standby chamber WM2. The third transfer chamber TM3 is adjacent to the second transfer chamber TM2 via the third standby chamber WM3. The fourth transfer chamber TM4 is adjacent to the third transfer chamber TM3 via the fourth standby chamber WM4.

The first to fourth process chambers PM11 to PM42 are arranged on both side surfaces (left and right sides in FIG. 1) of the first to fourth transfer chambers TM1 to TM4. Specifically, the first process chambers PM11 and PM12 are arranged on both side surfaces of the first transfer chamber TM1 when the first transfer chamber TM1 is viewed from the first standby chamber WM1. Similarly, the second process chambers PM21 and PM22 are arranged on both side surfaces of the second transfer chamber TM2. The third process chambers PM31 and PM32 are arranged on both side surfaces of the third transfer chamber TM3. The fourth process chambers PM41 and PM42 are arranged on both side surfaces of the fourth transfer chamber TM4.

Hereinafter, the first to fourth process chambers PM11 to PM42 may be collectively referred to simply as a “process chamber PM”. Similarly, the first to fourth standby chambers WM1 to WM4 may be collectively referred to simply as a “standby chamber WM”. The first to fourth transfer robots TH1 to TH4 may be collectively referred to simply as a “transfer robot TH”. The first to fourth transfer chambers TM1 to TM4 may be collectively referred to simply as a “transfer chamber TM”.

Hereinafter, each component of the substrate processing apparatus 100 will be described in more detail.

### Load Port

The load ports (I/O stages) LP1 and LP2 are used as a loading and unloading section of pods PD1 and PD2 used as wafer carriers. The inside of the pods PD1 and PD2 is configured such that an unprocessed wafer to be a processed in the process chamber PM (hereinafter, it may be referred to as an “unprocessed wafer”) and a processed wafer having been processed in the process chamber PM (hereinafter, it may be referred to as a “processed wafer”) are stored in a horizontal posture. By opening the front lids of the pods PD1 and PD2, the inside of the pods PD1 and PD2 communicates with the inside of the atmospheric transfer chamber LH.

### Atmospheric Transfer Chamber

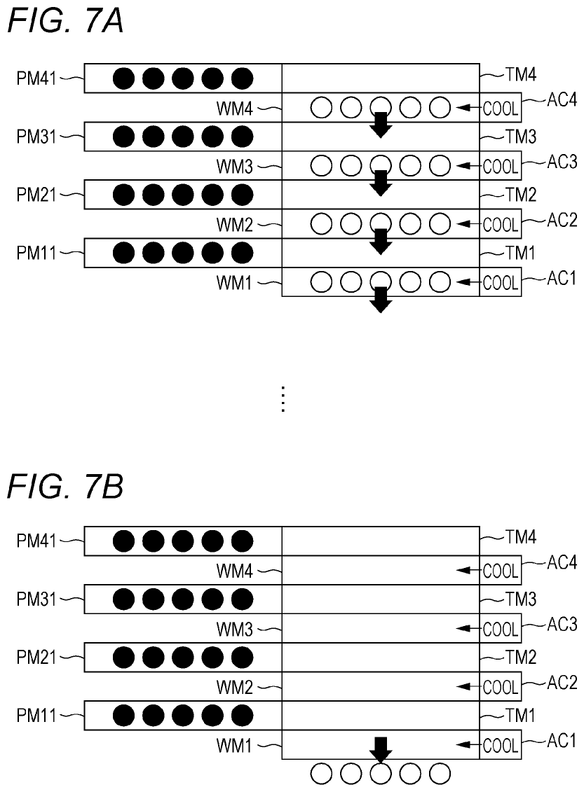

One side surface of the load ports LP1 and LP2 is provided with the atmospheric transfer chamber LH. The inside of the atmospheric transfer chamber LH is provided with an atmospheric transfer robot (not illustrated) that transfers wafers between the pods PD1 and PD2 and the first standby chamber WM1. The atmospheric transfer robot transfers five wafers of a plurality of (e.g., 25) unprocessed wafers housed in the pods PD1 and PD2 to the first standby chamber WM1. The atmospheric transfer robot transfers the five processed wafers from the first standby chamber WM1 into the pods PD1 and PD2 (see FIGS. 7A and 7B). A clean gas such as an inert gas is supplied into the atmospheric transfer chamber LH and is held at atmospheric pressure.

### Standby Chamber

As illustrated in FIG. 1, the first standby chamber WM1 is provided on the side surface of the atmospheric transfer chamber LH on the opposite side where the load ports LP1 and LP2 are provided. A holding region for holding, in a horizontal posture five unprocessed wafers transferred from the pods PD1 and PD2 is provided inside the first standby chamber WM1, and an empty region for holding five processed wafers is provided below this holding region. A gate valve (not illustrated) is provided between the atmospheric transfer chamber LH and the first standby chamber WM1, and the inside of the atmospheric transfer chamber LH and the inside of the first standby chamber WM1 can communicate with each other by opening this gate valve.

The inside of the second to fourth standby chambers WM2 to WM4 is configured similarly to the inside of the first standby chamber WM1.

### Temperature Adjustment Mechanism

The first standby chamber WM1 is provided with the first temperature adjustment mechanism AC1 that adjusts the temperature in the first standby chamber WM1. The first temperature adjustment mechanism ACl includes a heating mechanism and a cooling mechanism. The heating mechanism heats the unprocessed wafer held in the first standby chamber WM1, and the cooling mechanism cools the processed wafer. Known techniques can be used for the heating mechanism and the cooling mechanism.

The second to fourth standby chambers WM2 to WM4 are also provided with the second to fourth temperature adjustment mechanisms AC2 to AC4 that have the same configuration and function as those of the first temperature adjustment mechanism AC1.

### Transfer Chamber

The first transfer chamber TM1 is provided on the side surface of the first standby chamber WM1 on the opposite side where the atmospheric transfer chamber LH is provided. The inside of the first transfer chamber TM1 is provided with the first transfer robot TH1 that transfers and holds the wafer. A gate valve (not illustrated) is provided between the first standby chamber WM1 and the first transfer chamber TM1, and the inside of the first standby chamber WM1 and the inside of the first transfer chamber TM1 can communicate with each other by opening this gate valve. Similarly, gate valves (not illustrated) are also provided between the first transfer chamber TM1 and the first process chamber PM11 and between the first transfer chamber TM1 and the first process chamber PM12.

The inside of the second to fourth transfer chambers TM2 to TM4 is configured similarly to the inside of the first transfer chamber TM1.

### Transfer Robot

The first transfer robot TH1 includes a pair of arms AR11 and AR12 that temporarily hold and transfer the wafer. The first transfer robot TH1 transfers the unprocessed wafer held in the first standby chamber WM1 to the second standby chamber WM2, and transfers the processed wafer held in the second standby chamber WM2 to the first standby chamber WM1. The first transfer robot TH1 is configured to be able to perform swap (replacement) transfer in which, for example, an unprocessed wafer is placed on the arm AR11 and loaded into the first process chamber PM11, and a processed wafer is placed on the arm AR12 and unloaded from the first process chamber PM11.

The inside of the second to fourth transfer chambers TM2 to TM4 is also provided with the second to fourth transfer robots TH2 to TH4 that have the same configuration and function as those of the first transfer robot TH1.

### Process Chamber

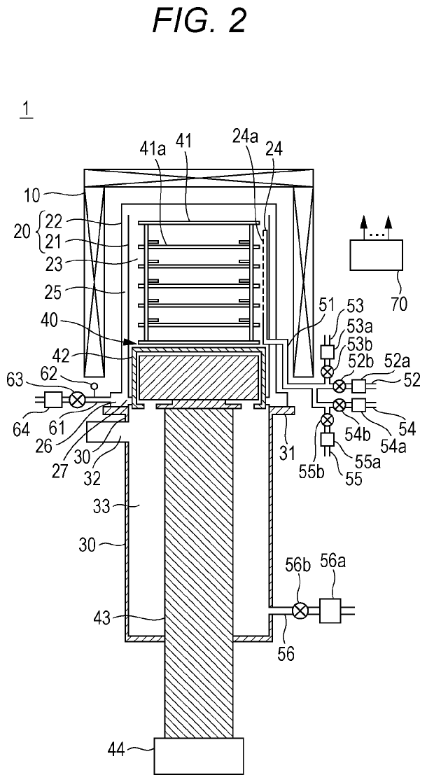

Both side surfaces (left and right sides in FIG. 1) of the first transfer chamber TM1 when the first transfer chamber TM1 is viewed from the first standby chamber WM1 are provided with the first process chambers PM11 and PM12 that perform processing such as film forming on the wafer. Although not illustrated in FIG. 1, a vertical process furnace 1 (see FIG. 2) that performs film forming on wafers is disposed inside the process chambers PM11 and PM12. The configuration of the vertical process furnace 1 will be described later.

The inside of the second to fourth process chambers PM21 to PM42 is also provided with a vertical process furnace that has the same configuration and function as those of the vertical process furnace 1.

### (2) Configuration Example of Process Chamber

The process chamber PM included in the substrate processing apparatus 100 of the present disclosure is configured as a vertical substrate process chamber that collectively processes five wafers of the process target. Hereinafter, the vertical process furnace 1 included in the first process chamber PM11 will be described as an example.

Examples of the processing performed on the wafer by the process chamber PM include oxidizing, diffusing, reflow and anneal for carrier activation and planarization after ion implantation, and film forming. In the present disclosure, in particular, a case of performing film forming is taken as an example.

Hereinafter, the configuration of the process chamber PM will be specifically described with reference to the drawings.

FIG. 2 is a side cross-sectional view that schematically illustrates a schematic configuration example of the inside of the first process chamber PM11 included in the substrate processing apparatus 100 of the present disclosure.

### Overall Configuration

The vertical process furnace 1 includes a heater 10 as a heater in order to uniformly heat a reaction tube 20 described later. The heater 10 has a cylindrical shape and is supported by a heater base (not illustrated) as a holding plate, whereby the heater 10 is installed perpendicularly to the installation floor of the substrate processing apparatus.

Inside the heater 10, the reaction tube 20 that constitutes a reaction container is disposed concentrically with the heater 10.

A lower chamber (load lock chamber) 30 that constitutes a load lock chamber for substrate transfer is disposed below the reaction tube 20.

In a space formed by the reaction tube 20 and the lower chamber 30, a substrate support 40 for supporting a wafer of the process target is disposed movably in the vertical direction in the space.

### Reaction Tube

The reaction tube 20 is made of a heat-resistant material such as quartz (SiO₂) or silicon carbide (SiC) and is formed in a cylindrical shape having a double tube structure including an inner tube 21 and an outer tube 22.

The inside of the inner tube 21 (i.e., the inside of the hollow cylinder) is provided with a processor 23 that processes the wafer. The processor 23 is configured to be able to accommodate wafers supported by a boat 41 of the substrate support 40 described later in a state where the wafers are arranged in multiple stages in the vertical direction in a horizontal posture.

The inside of the processor 23 is provided with a nozzle 24 that extends from a lower region to an upper region of the processor 23. The nozzle 24 is provided with a plurality of gas supply holes 24a arranged along the extending direction of the nozzle 24 at positions opposing the wafers supported by the boat 41. Due to this, gas is supplied from the gas supply holes 24a of the nozzle 24 to the wafers.

An exhaust flow path 25 through which gas flows is formed outside the inner tube 21 and inside the outer tube 22. The exhaust flow path 25 is configured such that gas flows from the processor 23 through a gap between the upper end of the outer tube 22 and the upper end of the inner tube 21, and the flown gas flows downward in a space between the outside of the inner tube 21 and the inside of the outer tube 22.

In a lower section of the outer tube 22, a pumping section 26 as an exhaust buffer that is a gas retention space is formed so as to surround the outer tube 22.

A lower section of the inner tube 21 is provided with an aperture 27 at a position opposing the pumping section 26. The apertures 27 are provided at a plurality of positions around the position where the pumping section 26 is disposed in the lower section of the inner tube 21, and are configured to discharge gas from the inside of the inner tube 21 to the pumping section 26.

### Gas Supplier

A gas supply pipe 51 as a gas supply line is connected to the nozzle 24 disposed inside the inner tube 21 so as to penetrate the inner tube 21 and the outer tube 22. At least two gas supply pipes 52 and 54 are connected to the gas supply pipe 51, and are configured to be able to supply a plurality of types of gases into the processor 23.

On the flow path of the gas supply pipe 52, a mass flow controller (MFC) 52a, which is a flow rate controller, and a valve 52b, which is an on-off valve, are provided in order from the upstream direction. On the downstream side relative to the valve 52b, a gas supply pipe 53 for supplying an inert gas is connected to the gas supply pipe 52. The gas supply pipe 53 is provided with an MFC 53a and a valve 53b in order from the upstream direction. The gas supply pipe 52, the MFC 52a, and the valve 52b mainly constitute a first process gas supplier, which is a first process gas supply system.

On the flow path of the gas supply pipe 54, an MFC 54a and a valve 54b are provided in order from the upstream direction. On the downstream side relative to the valve 54b, a gas supply pipe 55 for supplying an inert gas is connected to the gas supply pipe 54. The gas supply pipe 55 is provided with an MFC 55a and a valve 55b in order from the upstream direction. The gas supply pipe 54, the MFC 54a, and the valve 54b mainly constitute a second process gas supplier, which is a second process gas supply system.

From the gas supply pipe 52, as the first process gas, a source gas (first metal-containing gas, first source gas) containing the first metal element is supplied into the processor 23 via the MFC 52a, the valve 52b, the gas supply pipe 51, and the nozzle 24.

From the gas supply pipe 54, as the second process gas, a reactant gas is supplied into the processor 23 via the MFC 54a, the valve 54b, the gas supply pipe 51, and the nozzle 24. As the reactant gas, for example, ammonia (NH₃) gas as an N-containing gas containing nitrogen (N) can be used. The NH₃ gas acts as a nitriding/reducing agent (nitriding/reducing gas).

From the gas supply pipes 53 and 55, as an inert gas, for example, nitrogen (N₂) gas is supplied into the processor 23 via the MFCs 53a and 55a, the valves 53b and 55b, respectively, the gas supply pipe 51, and the nozzle 24.

### Gas Exhaust System

An exhaust pipe 61 that exhausts the gas retained in the pumping section 26 is connected to the pumping section 26. A pressure sensor 62 as a pressure detector that detects the pressure in the processor 23, an auto pressure controller (APC) valve 63, and a vacuum pump 64 as a vacuum exhaust device are connected to the exhaust pipe 61 in order from the upstream side.

### Lower Chamber

The lower chamber 30 has a flange 31 that supports the reaction tube 20 at the upper end thereof. Since the flange 31 supports the reaction tube 20, the lower chamber 30 is disposed below the reaction tube 20.

The vicinity of the upper end of the lower chamber 30 is provided with a substrate loading and unloading port 32. The substrate loading and unloading port 32 is configured to allow wafers to get into and out of the lower chamber 30 by the first transfer robot TH1 (see FIG. 1).

An inert gas supply pipe 56 is connected to a lower section of the lower chamber 30. On the flow path of the inert gas supply pipe 56, an MFC 56a and a valve 56b are provided in order from the upstream direction. The inert gas supply pipe 56, the MFC 56a, and the valve 56b mainly constitute an inert gas supplier, which is a second inert gas supply system.

From the inert gas supply pipe 56, as an inert gas, for example, N₂ gas is supplied into the lower chamber 30.

### Substrate Support

The substrate support 40 is disposed movably in the space formed by the reaction tube 20 and the lower chamber 30, i.e., in the processor 23 in the inner tube 21 and a transfer chamber 33 in the lower chamber 30, and includes the boat 41 as a substrate support that supports the wafer and a heat insulator 42 disposed below the boat 41.

The boat 41 as a substrate support is provided with five stages of plates 41a, and the boat 41 is configured such that the plates 41a support five wafers aligned in the vertical direction in a horizontal posture and in a state where centers thereof are aligned with one another in multiple stages.

On the lower surface of the heat insulator 42, a support rod 43 that supports the heat insulator 42 from below is disposed. The support rod 43 is disposed so as to penetrate the bottom of the lower chamber 30 while maintaining the gastight state of the transfer chamber 33, and is coupled to an elevator mechanism (boat elevator) 44 outside the lower chamber 30.

The elevator mechanism 44 operates to elevate the boat 41, the heat insulator 42, and the support rod 43. The operation of the elevator mechanism 44 enables the substrate support 40 to move vertically in the processor 23 in the inner tube 21 and the transfer chamber 33 in the lower chamber 30.

Specifically, for example, when the elevator mechanism 44 performs an elevating operation, at least the boat 41 is positioned in the processor 23 as illustrated in FIG. 2, whereby the processing in the processor 23 can be performed on the wafers supported by the boat 41.

For example, when the elevator mechanism 44 performs a lowering operation, the boat 41 is lowered into the transfer chamber 33 of the lower chamber 30. In this way, the first transfer robot TH1 can place five wafers on the plate 41a of the boat 41 through the substrate loading and unloading port 32.

### (3) Controller

Hereinafter, the configuration of a controller 70 will be described with reference to the drawings.

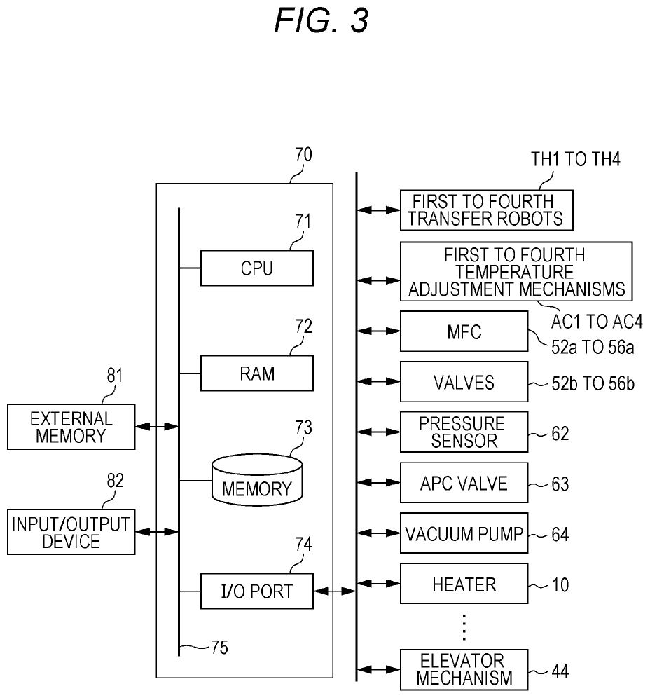

FIG. 3 is a block diagram that schematically illustrates a configuration example of a controller included in the substrate processing apparatus 100 of the present disclosure. The substrate processing apparatus of the present disclosure includes the controller 70 as a controller that controls the operation of each section in the substrate processing apparatus.

The controller 70 as a controller is configured as a computer that includes a central processing unit (CPU) 71 as an arithmetic section, a random access memory (RAM) 72 as a temporary memory, a memory 73 as a mass memory, and an I/O port 74. The RAM 72, the memory 73, and the I/O port 74 are configured to be able to exchange data with the CPU 71 via an internal bus 75. The controller 70 is configured to be connectable to, for example, an external memory 81 and an input/output device 82 such as a touchscreen.

The memory 73 is configured by, for example, a flash memory, a hard disk drive (HDD), and the like. The memory 73 readably stores a control program that controls the operation of the substrate processing apparatus, a process recipe in which processes and conditions of the method of manufacturing a semiconductor device described later are described, and the like. The process recipe has processes (steps) in the method of manufacturing a semiconductor device described later combined so as to cause the controller 70 to execute and obtain a predetermined result, and the process recipe functions as a program. Hereinafter, this process recipe, the control program, and the like are also collectively referred to simply as a program. Use of the term “program” in the present description includes a case of including only a process recipe, a case of including only a control program alone, and a case of including a combination of a process recipe and a control program. The RAM 72 is configured as a memory region (work area) in which a program, data, and the like read by the CPU 71 are temporarily held.

The I/O port 74 is connected to the first to fourth temperature adjustment mechanisms AC1 to AC4, the first to fourth transfer robots TH1 to TH4, the MFCs 52a to 56a, the valves 52b to 56b, the pressure sensor 62, the APC valve 63, the vacuum pump 64, the heater 10, the elevator mechanism 44, and the like.

The CPU 71 is configured to read a control program from the memory 73 and execute the control program, and to read a recipe and the like from the memory 73 in response to an input of an operation command or the like from the input/output device 82. The CPU 71 is configured to control the temperature regulation operation of the first to fourth temperature adjustment mechanisms AC1 to AC4, the transfer operation of the first to fourth transfer robots TH1 to TH4, the flow rate regulation operation of various gases by the MFCs 52a to 56a, the opening and closing operation of the valves 52b to 56b, the opening and closing operation of the APC valve 63, the pressure regulation operation based on the pressure sensor 62 by the APC valve 63, the temperature regulation operation of the heater 10, the start and stop of the vacuum pump 64, the elevation operation of the boat 41 by the elevator mechanism 44, the accommodation operation of the wafer into the boat 41, and the like via the I/O port 74 in accordance with the contents of the recipe having been read.

The controller 70 as described above may be configured as a dedicated computer or may be configured as a general-purpose computer. The controller 70 of the present disclosure can be configured by preparing an external memory (e.g., a magnetic tape, a magnetic disk such as a flexible disk or a hard disk, an optical disk such as a CD or a DVD, a magneto-optical disk such as an MO, or a semiconductor memory such as a USB memory (USB flash drive) or a memory card) 81 storing the above-described program, for example, and installing the program into a general-purpose computer using the external memory 81. The means for supplying the program to the computer is not limited to the case of supplying the program via the external memory 81. For example, a communication means such as the Internet or a dedicated line may be used, or information may be received from a higher-level device via a reception section, and the program may be supplied not via the external memory 81.

The memory 73 in the controller 70 and the external memory 81 connectable to the controller 70 are configured as non-transitory computer-readable recording media. Hereinafter, these are collectively referred to simply as a recording medium. Use of the term “recording medium” in the present description includes a case of including only the memory 73 alone, a case of including only the external memory 81 alone, and a case of including both of them.

### (4) Substrate Processing (Film Forming) in Process Chamber

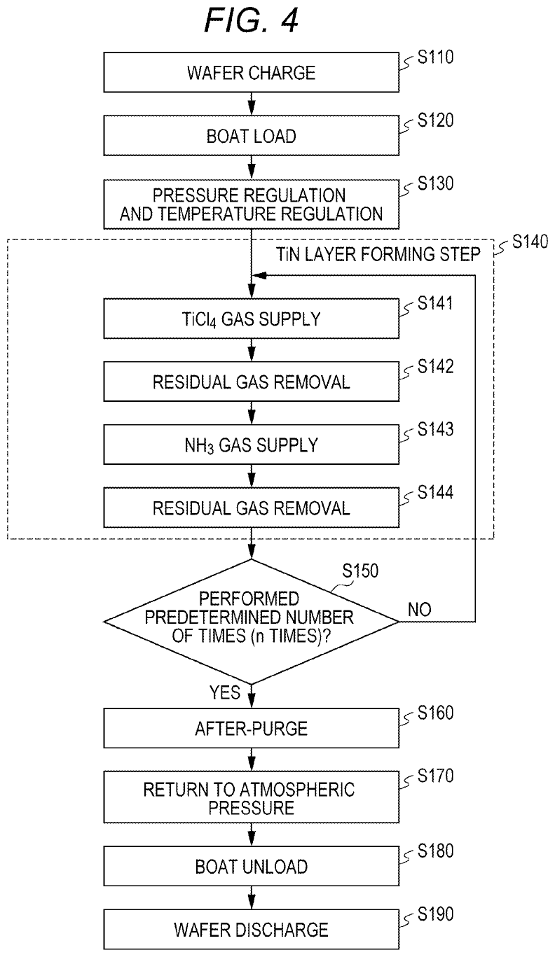

Next, the substrate processing in the process chamber PM will be described with reference to FIGS. 2 and 4. Here, as the substrate processing, formation (film forming) of a titanium nitride (TiN) layer, which is an example of a metal film, onto a wafer will be described as an example. In the following description, the operation of each section that constitutes the process chamber PM is controlled by the controller 70.

Hereinafter, film forming performed in the first process chamber PM11 will be described as an example.

### Wafer Charge: S110

In the film forming, first, a wafer to be a workpiece is charged (wafer charge) into the boat 41. Specifically, in the transfer chamber 33, the plate 41a of the boat 41 is disposed at a position opposing the substrate loading and unloading port 32, and in this state, the first transfer robot TH1 places the wafer onto the plate 41a through the substrate loading and unloading port 32. This is performed for each of the plates 41a of the five stages while moving the vertical position of the boat 41 by the elevator mechanism 44. Due to this, the boat 41 is charged with five wafers.

### Boat Load: S120

After the wafers are charged into the boat 41, the boat 41 is subsequently elevated by the elevator mechanism 44. This causes the five wafers charged into the boat 41 to be loaded into the processor 23 (boat load).

### Pressure Regulation and Temperature Regulation: S130

After the wafers are loaded into the processor 23, the vacuum pump 64 is operated so that the inside of the processor 23 has a desired pressure (degree of vacuum). At this time, the pressure in the processor 23 is measured by the pressure sensor 62, and the APC valve 63 is feedback-controlled (pressure regulation) based on this measured pressure information. The vacuum pump 64 maintains a state of being constantly operated at least until the processing on the wafer is completed. Heating by the heater 10 is performed so that the inside of the processor 23 has a desired temperature. At this time, the current-carrying quantity to the heater 10 is feedback-controlled (temperature regulation) based on the temperature information detected by the temperature sensor so that the inside of the processor 23 has a desired temperature distribution. The heating in the processor 23 by the heater 10 is continuously performed at least until the processing on the wafer is completed.

### TiN Layer Forming: S140

When the atmosphere in the processor 23 is stabilized, next, the process proceeds to a TiN layer forming (S140) as film forming. In the TiN layer forming (S140), steps of supplying a titanium tetrachloride gas (S141), removing a residual gas (S142), supplying an NH₃ gas (S143), and removing a residual gas (S144) are sequentially performed.

### Supply of Titanium Tetrachloride Gas: S141

Specifically, after the atmosphere in the processor 23 is stabilized, the valve 52b is opened, and the titanium tetrachloride gas that is the source gas is caused to flow through the gas supply pipe 52 and the gas supply pipe 51. The flow rate of the titanium tetrachloride gas is regulated by the MFC 52a. The titanium tetrachloride gas is supplied into the processor 23 from the gas supply hole 24a of the nozzle 24, and is exhausted from the exhaust pipe 61 through the exhaust flow path 25 and the pumping section 26. Due to this, the titanium tetrachloride gas is supplied to the wafers charged in the boat 41. The valve 53b is opened in accordance with the supply of the titanium tetrachloride gas, and an inert gas such as N₂ gas is caused to flow into the gas supply pipe 53. The flow rate of the N₂ gas flowing through the gas supply pipe 53 is regulated by the MFC 53a. The N₂ gas is supplied into the processor 23 together with the titanium tetrachloride gas, and is exhausted from the exhaust pipe 61.

At this time, the APC valve 63 is regulated to set the pressure in the processor 23 to a pressure within a range of 0.1 to 6650 Pa, for example. The supply flow rate of the titanium tetrachloride gas controlled by the MFC 52a is a flow rate within a range of 0.1 to 2 slm, for example. The supply flow rate of the N₂ gas controlled by the MFC 53a is a flow rate within a range of 0.1 to 30 slm, for example. The time for supplying the titanium tetrachloride gas to the wafer is in a range of 0.01 to 20 seconds, for example. The heater 10 sets the temperature of the wafer to a temperature within a range of 250 to 550° C., for example.

Thus, when the titanium tetrachloride gas and the N₂ gas are supplied into the processor 23, a Ti-containing layer having a thickness of, for example, less than monolayer to about several atomic layers is formed on the wafers (base film on the surface) charged in the boat 41.

At this time, an inert gas such as N₂ gas is supplied also into the transfer chamber 33. Specifically, the valve 56b is opened, and an inert gas such as N₂ gas is caused to flow into the inert gas supply pipe 51. The flow rate of the N₂ gas flowing through the inert gas supply pipe 51 is regulated by the MFC 56a and is supplied into the transfer chamber 33. The N₂ gas is supplied into the transfer chamber 33 such that the gas pressure in the processor 23<the gas pressure in the transfer chamber 33. The N₂ gas is supplied into the transfer chamber 33 such that the total flow rate of the gas supplied into the processor 23<the flow rate of the gas supplied into the transfer chamber 33.

### Residual Gas Removal: S142

After the Ti-containing layer is formed on the wafer, the valve 52b is closed, and the supply of the titanium tetrachloride gas is stopped. At this time, with the APC valve 63 of the exhaust pipe 61 opened, the inside of the processor 23 is vacuum-exhausted by the vacuum pump 64, and the titanium tetrachloride gas that is residual in the processor 23 and having not reacted or having contributed to the formation of the Ti-containing layer is excluded from the processor 23. With the valve 53b opened, the supply of the N₂ gas into the processor 23 is maintained. The N₂ gas acts as a purge gas, and it is possible to enhance an effect of excluding, from the processor 23, the titanium tetrachloride gas that is residual in the processor 23 and having not reacted or having contributed to the formation of the Ti-containing layer.

### NH₃ Gas Supply: S143

After the residual gas in the processor 23 is removed, the valve 54b is opened, and the NH₃ gas, which is an N-containing gas, is caused to flow as a reactant gas to the gas supply pipe 54 and the gas supply pipe 51. The flow rate of the NH₃ gas is regulated by the MFC 54a. The titanium tetrachloride gas is supplied into the processor 23 from the gas supply hole 24a of the nozzle 24, and is exhausted from the exhaust pipe 61 through the exhaust flow path 25 and the pumping section 26. Due to this, the NH₃ gas is supplied to the wafers charged in the boat 41. At this time, with the valve 55b closed, the N₂ gas is not supplied into the processor 23 together with the NH₃ gas. That is, the NH₃ gas is supplied into the processor 23 without being diluted with the N₂ gas, and is exhausted from the exhaust pipe 61. Thus, when the reactant gas (NH₃ gas) is supplied into the processor 23 without being diluted with the N₂ gas, the film-forming rate of the TiN layer can be improved.

When the NH₃ gas flows, the APC valve 63 is regulated to set the pressure in the processor 23 to a pressure within a range of 0.1 to 6650 Pa, for example. The supply flow rate of the NH₃ gas controlled by the MFC 54a is a flow rate within a range of 0.1 to 20 slm, for example. The time for supplying the NH₃ gas to the wafer is in a range of 0.01 to 30 seconds, for example. The heater 10 is set to a temperature similar to that in the titanium tetrachloride gas supply.

Thus, when the NH₃ gas is supplied into the processor 23, the NH₃ gas undergoes a substitution reaction with at least a part of the Ti-containing layer formed on the wafer in the titanium tetrachloride gas supply. By this substitution reaction, Ti contained in the Ti-containing layer and N contained in the NH₃ gas are combined, and a TiN layer containing Ti and N is formed on the wafer charged in the boat 41.

Also at this time, similarly to the case of the titanium tetrachloride gas supply (S141) described above, an inert gas such as an N₂ gas is supplied into the transfer chamber 33. Since the specific processing is the same as that in the case of the titanium tetrachloride gas supply (S141), the description thereof is omitted here.

### Residual Gas Removal: S144

After the TiN layer is formed on the wafer, the valve 54b is closed to stop the supply of the NH₃ gas. Then, the NH₃ gas that is residual in the processor 23 and having not reacted or having contributed to the formation of the TiN layer and reaction by-products are excluded from the processor 23 by the same process as that in the case of the residual gas removal described above.

### Confirmation of the Number of Executions: S150

When the cycle of sequentially performing the steps (S141 to S144) in the TiN layer forming (S140) described above is ended, it is determined whether or not the cycle is performed a preset number of times (predetermined number of times) each time. Then, the cycle is repeatedly performed until it is performed the predetermined number of times (S141 to S144). The number of times of repeating the above-described cycle is preferably about 10 to 80 times, for example, and more preferably about 10 to 15 times. Then, by repeating the above-described cycle the predetermined number of times, a TiN layer having a predetermined thickness (e.g., 0.1 to 2 nm) is formed on the wafer.

### After-Purge: S160

After the above-described cycle is repeated the predetermined number of times, the N₂ gas is supplied from each of the gas supply pipes 53 and 55 into the processor 23 and is exhausted from the exhaust pipe 61. The N₂ gas acts as a purge gas, whereby the inside of the processor 23 is purged with an inert gas, and the gas that is residual in the processor 23 and by-products are removed from the inside of the processor 23.

### Atmospheric Pressure Return: S170

After the inside of the processor 23 is purged, the atmosphere in the processor 23 is substituted with an inert gas (inert gas substitution), and the pressure in the processor 23 is returned to normal pressure.

### Boat Unload: S180

Thereafter, the boat 41 is lowered by the elevator mechanism 44 in a reverse process to the above-described boat load (S120), and each wafer charged in the boat 41 is unloaded from the processor 23 (boat unload).

### Wafer Discharge: S190

Then, after the boat 41 is unloaded, the processed wafers are taken out from the boat 41 by the first transfer robot TH1 and unloaded to the outside of the lower chamber 30 through the substrate loading and unloading port 32 in a reverse process to the wafer charge (S110) described above.

Thus, the film forming of the TiN layer on the five wafers is completed.

In the first to fourth process chambers PM12 to PM42, which are other process chambers, a similar film forming is performed.

### (5) Substrate Transfer in Substrate Processing Apparatus

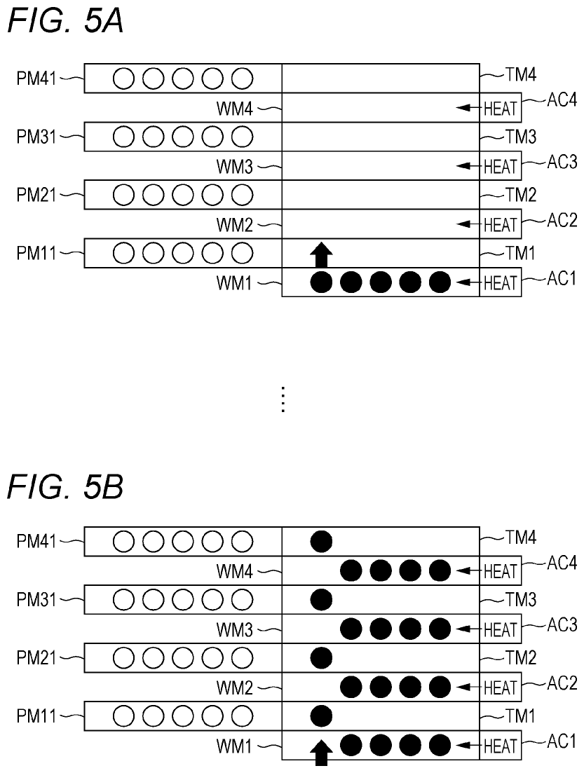

Next, the transfer of the wafer before and after the film forming described above is divided into (i) pre-swapping, which is immediately before the unprocessed wafer is unloaded from the first standby chamber WM1 and loaded into the process chamber PM, (ii) swapping, which is to exchange the processed wafer with the unprocessed wafer, and (iii) post-swapping, which is to load, into the first standby chamber WM1, the processed wafer unloaded from the process chamber PM. The transfer of the wafer will be described with reference to FIGS. 1 and 5A to 7B. In the following description, the wafer transfer from the first standby chamber WM1 to the first to fourth process chambers PM11, PM21, PM31, and PM41 will be described as an example. In FIGS. 5A to 7B, the first to fourth process chambers PM12, PM22, PM32, and PM42, the first to fourth transfer robots TH1 to TH4, and the atmospheric transfer chamber LH are omitted. In FIGS. 5A to 7B, for convenience, the first to fourth temperature adjustment mechanisms AC1 to AC4 are illustrated outside the standby chamber WM. In FIGS. 5A to 7B, white circles indicate processed wafers, and black circles indicate unprocessed wafers. In the following description, the operation of each section that constitutes the substrate processing apparatus 100 is controlled by the controller 70.

### Pre-Swapping

In the pre-swapping, first, transfer of five unprocessed wafers held in the first standby chamber WM1 to the fourth standby chamber WM4 (hereinafter, it may be referred to as “step A”) is performed. Step A will be described below. Note that the transfer of the wafer described below is performed in accordance with the number (two) of arms included in the transfer robot TH that transfers the wafers, and the transfer of the five wafers is performed several times by 1 or 2 sheets.

### Step A

The wafer held in the first standby chamber WM1 is held by the first transfer robot TH1 and transferred to the second standby chamber WM2 via the first transfer chamber TM1. Subsequently, this wafer is held by the second transfer robot TH2 and transferred to the third standby chamber WM3 via the second transfer chamber TM2. Subsequently, this wafer is held by the third transfer robot TH3 and transferred to the fourth standby chamber WM4 via the third transfer chamber TM3. The above operation is repeatedly performed until all the five wafers held in the first standby chamber WM1 are transferred to the fourth standby chamber WM4. Finally, the fourth transfer robot TH4 holds one of the five wafers held in the fourth standby chamber WM4, transfers the wafer to the fourth transfer chamber TM4, and ends step A.

When all the five wafers held in the first standby chamber WM1 are unloaded in step A, transfer of new five unprocessed wafers to the third standby chamber WM3 (hereinafter, this step is referred to as “step B”) is started. Step B is performed in the same manner as step A.

When all the five wafers held in the first standby chamber WM1 are unloaded in step B, transfer of new five unprocessed wafers to the second standby chamber WM2 (hereinafter, this step is referred to as “step C”) is started. Step C is performed in the same manner as step A.

In step C, when all the five wafers held in the first standby chamber WM1 are unloaded, the first transfer robot TH1 holds one of the new five unprocessed wafers and transfers the wafer to the first transfer chamber TM1 (see FIGS. 5A and 5B).

This completes the pre-swapping.

### Swapping

In the swapping, first, one arms included in the first to fourth transfer robots TH1 to TH4 hold the processed wafers processed in the first to fourth process chambers PM11 to PM41, respectively. Subsequently, these processed wafers and the unprocessed wafers held by the other arms of the first to fourth transfer robots TH1 to TH4 in the pre-swapping are exchanged. That is, the processed wafers are transferred to the first to fourth standby chambers WM1 to WM4, and the unprocessed wafers are transferred to the first to fourth process chambers PM11 to PM41. At this time, the four wafers held in the first to fourth standby chambers WM1 to WM4 are simultaneously transferred to the first to fourth process chambers PM11 to PM41, respectively.

The term “simultaneous” as used herein includes not only exactly the same timing but also substantially the same timing and approximate timing. In the present description, the term “simultaneous” used hereinafter has the same meaning.

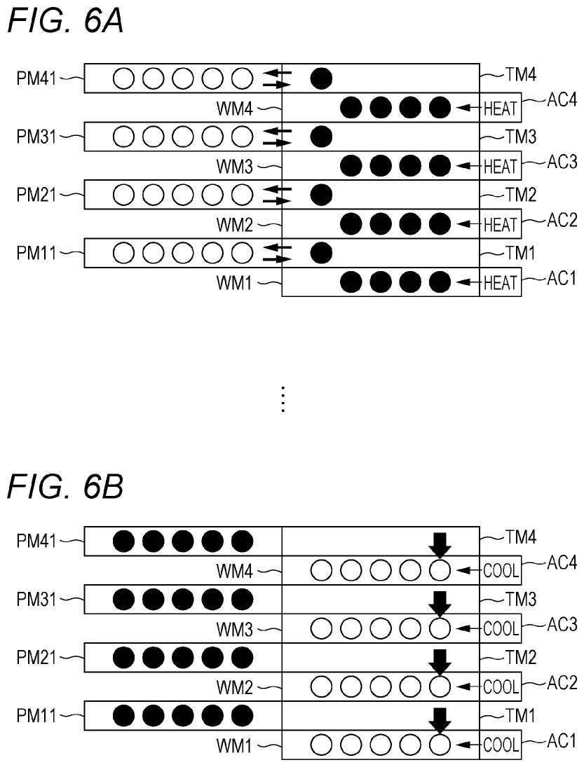

The above operation is repeatedly performed until all the wafers held in the standby chamber WM and all the wafers processed in the process chamber PM are swapped, and the swapping is ended (see FIGS. 6A and 6B).

### Post-Swapping

In the post-swapping, the processed wafer is transferred to the first standby chamber WM1 by the transfer robot TH in a reverse process to the pre-swapping (see FIGS. 7A and 7B).

The transfer of the wafer from the first standby chamber WM1 to the first to fourth process chambers PM12, PM22, PM32, and PM42 is also performed in the same manner as described above.

### (6) Operation Example of Temperature Adjustment Mechanism

Next, an operation example of the temperature adjustment mechanism AC in the substrate transfer will be described with reference to FIGS. 5A to 7B. The operation of the temperature adjustment mechanism AC is controlled by the controller 70.

Hereinafter, the operation example of the temperature adjustment mechanism AC will be described separately for temperature adjustment by the heating mechanism of the temperature adjustment mechanism AC and temperature adjustment by the cooling mechanism.

### Temperature Adjustment by Heating Mechanism

As illustrated in FIGS. 5A and 5B, in the pre-swapping, the heating mechanism of the temperature adjustment mechanism AC is operated to heat in advance the unprocessed wafer before being loaded into the process chamber PM. Thus, by operating the heating mechanism of the temperature adjustment mechanism AC provided in the transfer path of the wafer to the process chamber PM to preheat the wafer being transferred, it is possible to shorten the time from the loading of the wafer into the process chamber PM to the start of the film forming. As a result, it is possible to improve work efficiency.

Furthermore, in the pre-swapping, the heating mechanism of the temperature adjustment mechanism AC is operated to equalize the temperatures of the four wafers when being loaded into the four process chambers PM. As described above, in the swapping, since the four wafers held in the four transfer chambers TM are simultaneously loaded into the process chamber PM (see FIGS. 6A and 6B), the processing times of the four process chambers PM can be equalized by equalizing the temperatures of the four wafers at the time of loading. As a result, it is possible to further improve work efficiency.

As illustrated in FIGS. 5A and 5B, the transfer paths from the first standby chamber WM1 to the process chamber PM of the four wafers processed in the first to fourth process chambers PM11 to PM41 are different from one another. The preheating (heating) time of the wafer varies depending on the transfer path. Specifically, of the four wafers loaded into the process chamber PM, the total heating time for the wafer to be processed in the fourth process chamber PM41 is the longest, and the total heating time decreases in the order of the wafer to be processed in the third process chamber PM31, the wafer to be processed in the second process chamber PM21, and the wafer to be processed in the first process chamber PM11.

The temperature of the wafer immediately before being loaded into the process chamber PM is determined by the heating energy quantity of the heating mechanism (heating time of the heating mechanism×heating power of the heating mechanism).

Therefore, when the heating time and the heating power of the four temperature adjustment mechanisms AC1 to AC4 are set to be the same, for example, of the four wafers, the wafer to be processed in the fourth process chamber PM41, which has the longest total heating time, becomes the highest temperature, and the four wafers do not become the same temperature.

Therefore, the substrate processing apparatus 100 of the present disclosure changes the mode of temperature adjustment of the temperature adjustment mechanism AC depending on the transfer path of the wafer, and equalizes the total heating energy quantity for each wafer immediately before being loaded into the process chamber PM so that these wafers have the same temperature.

Specifically, any of the following control processing is performed.

### (i) First Control Mode

In the first control mode, the heating time in each standby chamber WM for the four wafers is made constant, and the heating power of the four heating mechanisms is controlled so as to vary depending on the wafer. For example, when the heating times of the first to fourth temperature adjustment mechanisms AC1 to AC4 are T (constant) and the heating powers of the first to fourth temperature adjustment mechanisms AC1 to AC4 are P1, P2, P3, and P4 (variables), respectively, the heating energy quantity for the wafer to be processed in the fourth process chamber PM41 is T×(P1+P2+P3+P4). Similarly, the heating energy quantity for the wafer to be processed in the third process chamber PM31 is T×(P1+P2+P3). The heating energy quantity for the wafer to be processed in the second process chamber PM21 is T×(P1+P2). The heating energy quantity for the wafer to be processed in the first process chamber PM11 is T×P1.

Since T is a constant, in order to equalize the heating energy quantity for each wafer, the values of P1 to P4 are set such that P1, P1+P2, P1+P2+P3, and P1+P2+P3+P4, which are the total heating power for the wafers to be processed in the first to fourth process chambers PM11 to PM41, become equal.

Note that, since P1 to P4 are variables, there is a case where different values are set even if the same reference sign is given. For example, even for the heating power P1 generated by the heating mechanism of the same first temperature adjustment mechanism AC1, different values are set for the heating power P1 for the wafer to be processed in the first process chamber PM11 and the heating power P1 for the wafer to be processed in the second process chamber PM21. Thus, even the value of the heating power P1 of the same heating mechanism is set to vary depending on the transfer destination (transfer path) of the wafer of the process target.

Thus, by equalizing the total heating energy quantity for each wafer, these wafers can be made to be the same in temperature.

Hereinafter, the above-described control will be specifically described with an example of the wafer to be processed in the fourth process chamber PM41.

(a) When the wafer to be processed in the fourth process chamber PM41 is transferred to the first standby chamber WM1, the controller 70 instructs the heating mechanism of the first temperature adjustment mechanism AC1 to heat this wafer with the heating power of P1 for T hours. The heating power of P1 is P1 of P1+P2+P3+P4, which is the total heating power for the wafer to be processed in the fourth process chamber PM41, and is set as the heating power generated by the heating mechanism of the first temperature adjustment mechanism AC1. T hours is a time set as a time from when the wafer is loaded into the first standby chamber WM1 to when the wafer is unloaded therefrom.

(b) When T hours has elapsed, the controller 70 instructs the first transfer robot TH1 to transfer the wafer to the second standby chamber WM2.

(c) When the first transfer robot TH1 transfers the wafer to the second standby chamber WM2, the controller 70 instructs the heating mechanism of the second temperature adjustment mechanism AC2 to heat the wafer with the heating power of P2 for T hours. The heating power of P2 is P2 of P1+P2+P3+P4, which is the total heating power for the wafer to be processed in the fourth process chamber PM41, and is set as the heating power generated by the heating mechanism of the second temperature adjustment mechanism AC2. T hours is a time set as a time from when the wafer is loaded into the second standby chamber WM2 to when the wafer is unloaded therefrom.

(d) When T hours has elapsed, the controller 70 instructs the second transfer robot TH2 to transfer the wafer to the third standby chamber WM3.

(e) When the second transfer robot TH2 transfers the wafer to the third standby chamber WM3, the controller 70 instructs the heating mechanism of the third temperature adjustment mechanism AC3 to heat the wafer with the heating power of P3 for T hours. The heating power of P3 is P3 of P1+P2+P3+P4, which is the total heating power for the wafer to be processed in the fourth process chamber PM41, and is set as the heating power generated by the heating mechanism of the third temperature adjustment mechanism AC3. T hours is a time set as a time from when the wafer is loaded into the third standby chamber WM3 to when the wafer is unloaded therefrom.

(f) When T hours has elapsed, the controller 70 instructs the third transfer robot TH3 to transfer the wafer to the fourth standby chamber WM4.

(g) When the third transfer robot TH3 transfers the wafer to the fourth standby chamber WM4, the controller 70 instructs the heating mechanism of the fourth temperature adjustment mechanism AC4 to heat the wafer with the heating power of P4 for T hours. The heating power of P4 is P4 of P1+P2+P3+P4, which is the total heating power for the wafer to be processed in the fourth process chamber PM41, and is set as the heating power generated by the heating mechanism of the fourth temperature adjustment mechanism AC4. T hours is a time set as a time from when the wafer is loaded into the fourth standby chamber WM4 to when the wafer is unloaded therefrom.

Since the processing is performed by the processes of (a) to (g), the total heating power for the wafer to be processed in the fourth process chamber PM41 becomes P1+P2+P3+P4. P1 to P4 may be set to the same value, may be set to increase in the order of P1 to P4, or may be set to decrease in the order of P1 to P4.

Similarly, since the processing is performed to the wafer to be processed in the third process chamber PM31 by the processes of (a) to (e), the total heating power for the wafer to be processed in the third process chamber PM31 becomes P1+P2+P3.

Since the processing is performed to the wafer to be processed in the second process chamber PM21 by the processes of (a) to (c), the total heating power for the wafer to be processed in the second process chamber PM21 becomes P1+P2.

Since the processing is performed to the wafer to be processed in the first process chamber PM11 by the process of (a), the total heating power for the wafer to be processed in the first process chamber PM11 becomes P1.

In the first control mode, by performing the heating process as described above, it is possible to equalize the temperatures of the four wafers when being loaded into the four process chambers PM.

Moreover, by performing the heating process as described above to make the heating time in each standby chamber WM of the wafer constant and by changing the heating power of each temperature adjustment mechanism AC depending on the transfer destination of the wafer, it becomes possible to omit regulation of the heating time, and thus it is possible to perform the work quickly and improve the work efficiency.

### (ii) Second Control Mode

In the second control mode, the heating power of each heating mechanism for the four wafers is made constant, and the heating time in each standby chamber WM is controlled so as to vary depending on the wafer. For example, when the heating powers of the first to fourth temperature adjustment mechanisms AC1 to AC4 are P (constant) and the heating times of the first to fourth temperature adjustment mechanisms AC1 to AC4 are T1, T2, T3, and T4 (variable), respectively, the heating energy quantity for the wafer to be processed in the fourth process chamber PM41 is (T1+T2+T3+T4)×P. Similarly, the heating energy quantity for the wafer to be processed in the third process chamber PM31 is (T1+T2+T3)×P. The heating energy quantity for the wafer to be processed in the second process chamber PM21 is (T1+T2)×P. The heating energy quantity for the wafer to be processed in the first process chamber PM11 is T1×P.

Since P is a constant, in order to equalize the total heating energy quantity for each wafer, the values of T1 to T4 are set such that T1, T1+T2, T1+T2+T3, and T1+T2+T3+T4, which are the total heating times for the wafers to be processed in the first to fourth process chambers PM11 to PM41, become equal.

Note that, since T1 to T4 are variables, there is a case where different values are set even if the same reference sign is given. For example, even for the heating time T1 of the heating mechanism of the same first temperature adjustment mechanism AC1, different values are set for the heating time T1 for the wafer to be processed in the first process chamber PM11 and the heating time T1 for the wafer to be processed in the second process chamber PM21. Thus, even the value of the same heating time T1 of the same heating mechanism is set to vary depending on the transfer destination (transfer path) of the wafer of the process target.

Note that the specific control is performed in the same manner as in the first control mode described above with the heating power as a constant and the heating time as a variable. Thus, in the second control mode, it is possible to equalize the temperatures of the four wafers when being loaded into the four process chambers PM.

Moreover, by performing the heating process as described above to make the heating power of each heating mechanism for the wafer constant and by changing the heating time in each standby chamber WM depending on the transfer destination of the wafer, the heating mechanism does not have to be complicated, and thus it is possible to simplify the structure of the heating mechanism.

### (iii) Third Control Mode

In the third control mode, both the heating time in each standby chamber WM and the heating power of the heating mechanism for the four wafers are controlled so as to vary depending on the wafer. For example, when the heating times of the first to fourth temperature adjustment mechanisms AC1 to AC4 are T1, T2, T3, and T4 (variables), respectively, and the heating powers of the first to fourth temperature adjustment mechanisms AC1 to AC4 are P1, P2, P3, and P4 (variables), respectively, the heating energy quantity for the wafer to be processed in the fourth process chamber PM41 is (T1×P1)+(T2×P2)+(T3×P3)+(T4×P4). Similarly, the heating energy quantity for the wafer to be processed in the third process chamber PM31 is (T1×P1)+(T2×P2)+(T3×P3). The heating energy quantity for the wafer to be processed in the second process chamber PM21 is (T1×Pl)+(T2×P2). The heating energy quantity for the wafer to be processed in the first process chamber PM11 is T1×P1.

In order to equalize the total heating energy quantity for each wafer, the values of T1 to T4 and P1 to P4 are set such that T1×P1, (T1×P1)+(T2×P2), (T1×P1)+(T2×P2)+(T3×P3), and (T1×P1)+(T2×P2)+(T3×P3)+(T4×P4), which are the total heating energy quantity for the wafers to be processed in the first to fourth process chambers PM11 to PM41, become equal.

Note that, since T1 to T4 and P1 to P4 are variables, there is a case where different values are set even if the same reference sign is given. For example, even for the heating power P1 generated by the heating mechanism of the same first temperature adjustment mechanism AC1, different values are set for the heating power P1 for the wafer to be processed in the first process chamber PM11 and the heating power P1 for the wafer to be processed in the second process chamber PM21. Thus, even the value of the heating power P1 of the same heating mechanism is set to vary depending on the transfer destination (transfer path) of the wafer of the process target. Similarly, for example, even for the heating time T1 of the heating mechanism of the same first temperature adjustment mechanism AC1, different values are set for the heating time T1 for the wafer to be processed in the first process chamber PM11 and the heating time T1 for the wafer to be processed in the second process chamber PM21. Thus, even the value of the same heating time T1 of the same heating mechanism is set to vary depending on the transfer destination (transfer path) of the wafer of the process target.

Note that the specific control is performed in the same manner as in the first control mode described above with both the heating power and the heating time as variables. Thus, in the third control mode, it is possible to equalize the temperatures of the four wafers when being loaded into the four process chambers PM.

Moreover, by performing the heating process as described above to change both the heating time in each standby chamber WM and the heating power of the heating mechanism for the four wafers in accordance with the transfer destination of the wafer, the degree of freedom of combination of components increases, and thus it is possible to use a highly versatile apparatus.

### Temperature Adjustment by Cooling Mechanism

As illustrated in FIGS. 7A and 7B, in the post-swapping, the cooling mechanism of the temperature adjustment mechanism AC is operated to cool the processed wafer in the transfer path. Thus, by operating the cooling mechanism of the temperature adjustment mechanism AC provided in the transfer path of the wafer unloaded from the process chamber PM to cool the wafer being transferred, it is possible to shorten the standby time until transition to the next processing. As a result, it is possible to improve work efficiency.

Furthermore, in the post-swapping, the cooling mechanism of the temperature adjustment mechanism AC is operated to equalize the temperature of the processed wafer when being unloaded from the first standby chamber WM1. In this way, the next processing can be simultaneously performed on the plurality of wafers unloaded from the first standby chamber WM1. As a result, it is possible to improve work efficiency of the subsequent processing.

As illustrated in FIGS. 7A and 7B, the transfer paths of the wafers unloaded from the four process chambers PM to the first standby chamber WM1 are different from one another. The cooling time of the wafer varies depending on the transfer path. Specifically, of the four wafers unloaded from the process chamber PM and loaded into the first standby chamber WM1, the total cooling time for the wafer unloaded from the fourth process chamber PM41 is the longest, and the total cooling time decreases in the order of the wafer unloaded from the third process chamber PM31, the wafer unloaded from the second process chamber PM21, and the wafer unloaded from the first process chamber PM11.

The temperature of the wafer immediately before being unloaded from the first standby chamber WM1 is determined by the cooling energy quantity of the cooling mechanism (cooling time of the cooling mechanism×cooling power of the cooling mechanism).

Therefore, when the cooling time and the cooling power of the four temperature adjustment mechanisms AC1 to AC4 are set to be the same, for example, of the four wafers, the wafer unloaded from the fourth process chamber PM41, which has the longest total cooling time, becomes the lowest temperature, and the four wafers do not become the same temperature.

Therefore, the substrate processing apparatus 100 of the present disclosure changes the mode of temperature adjustment of the temperature adjustment mechanism AC depending on the transfer path of the wafer, and equalizes the total cooling energy quantity for each wafer immediately before being unloaded from the first standby chamber WM1 so that these wafers have the same temperature.

Specific control processing is performed similarly to the first to third control modes of the temperature adjustment by the heating mechanism described above, and thus a detailed description thereof will be omitted.

In the present description, the term “same temperature” includes not only exactly the same temperature but also substantially the same temperature and an approximate temperature.

### (7) Effects of the Present Disclosure

According to the present disclosure, one or a plurality of effects described below is obtained.

(a) In the present disclosure, since the controller 70 controls the temperature adjustment mechanism AC so as to change the mode of temperature adjustment of the standby chamber WM depending on the transfer path of the wafer, for example, the temperatures of the wafers passing through different transfer paths can be equalized at a predetermined timing. As described above, since it is possible to freely regulate the temperature of the wafer, as a result, it is possible to improve work efficiency.

(b) In the present disclosure, since the unprocessed wafer being transferred is heated in advance by the heating mechanism of the temperature adjustment mechanism AC provided in the transfer path of the wafer to the process chamber PM, it is possible to shorten the time from the loading of the wafer into the process chamber PM to the start of the film forming. As a result, it is possible to improve work efficiency.

(c) In the present disclosure, since the processed wafer being transferred is cooled by the cooling mechanism of the temperature adjustment mechanism AC provided in the transfer path of the wafer unloaded from the process chamber PM, it is possible to shorten the standby time until transition to the next processing. As a result, it is possible to improve work efficiency.

(d) In the present disclosure, the heating mechanism of the temperature adjustment mechanism AC is controlled depending on the transfer path of the wafer, thereby equalizing the temperatures of the four wafers when being loaded into the four process chambers PM, and these wafers are simultaneously loaded into the process chambers PM. In this way, it is possible to equalize the processing times of the four process chambers PM, and to further improve the work efficiency.

(e) In the present disclosure, the cooling mechanism of the temperature adjustment mechanism AC is controlled depending on the transfer path of the wafer, thereby equalizing the temperatures of the processed wafers when being unloaded from the first standby chamber WM1. In this way, since the next processing can be simultaneously performed on the plurality of wafers unloaded from the first standby chamber WM1, it is possible to improve work efficiency of the subsequent processing.

(f) In the present disclosure, when equalizing the temperatures of the four wafers when being loaded into the four process chambers PM, in a case of making the heating time in each standby chamber WM for the unprocessed wafer constant and changing the heating power of each temperature adjustment mechanism AC depending on the transfer destination of the wafer, it becomes possible to omit regulation of the heating time, and thus it is possible to perform the work quickly and improve the work efficiency.

(g) In the present disclosure, when equalizing the temperatures of the four wafers when being loaded into the four process chambers PM, in a case of making the heating power of each heating mechanism for the unprocessed wafer constant and changing the heating time in each standby chamber WM depending on the transfer destination of the wafer, the heating mechanism does not have to be complicated, and thus it is possible to simplify the structure of the heating mechanism.

(h) In the present disclosure, when equalizing the temperatures of the four wafers when being loaded into the four process chambers PM, in a case of changing both the heating time in each standby chamber WM and the heating power of the heating mechanism for the unprocessed wafer depending on the transfer destination of the wafer, the degree of freedom of combination of components increases, and thus it is possible to use a highly versatile apparatus.

(f) In the present disclosure, when equalizing the temperatures of the processed wafers when being unloaded from the first standby chamber WM1, in a case of making the cooling time in each standby chamber WM for the processed wafer constant and changing the cooling power of each temperature adjustment mechanism AC depending on the transfer source of the wafer, it becomes possible to omit regulation of the cooling time, and thus it is possible to perform the work quickly and improve the work efficiency.

(j) In the present disclosure, when equalizing the temperatures of the processed wafer when being unloaded from the first standby chamber WM1, in a case of making the cooling power of each heating mechanism for the processed wafer constant and changing the cooling time in each standby chamber WM depending on the transfer source of the wafer, the heating mechanism does not have to be complicated, and thus it is possible to simplify the structure of the cooling mechanism.

(k) In the present disclosure, when equalizing the temperature of the processed wafer when being unloaded from the first standby chamber WM1, in a case of changing both the cooling time in each standby chamber WM and the cooling power of the cooling mechanism for the processed wafer depending on the transfer source of the wafer, the degree of freedom of combination of components increases, and thus it is possible to use a highly versatile apparatus.

### Other Embodiments

One embodiment of the present disclosure has been specifically described above. However, embodiments of the present disclosure are not limited to the above-described embodiment, and various modifications can be made without departing from the gist of the present disclosure.

In the above disclosure, the temperature adjustment mechanism AC including both the heating mechanism and the cooling mechanism has been described as an example. However, the present disclosure is not limited to this, and the temperature adjustment mechanism AC may only include any one of the heating mechanism and the cooling mechanism.

In the above disclosure, the substrate processing apparatus 100 including four transfer chambers TM and four standby chambers WM has been described as an example. However, the present disclosure is not limited to this, and the substrate processing apparatus 100 may include equal to or less than three transfer chambers TM and three or less standby chambers WM or five or more transfer chambers TM and equal to or more than five standby chambers WM.

In the above disclosure, the substrate processing apparatus 100 in which the process chambers PM are provided on both side surfaces of the transfer chamber TM has been described as an example. However, the present disclosure is not limited to this, and the process chamber PM may be provided only on one side surface of the transfer chamber TM.

In the above disclosure, the description has been given with an example in which the unprocessed wafer to be loaded into the process chamber PM is heated by all the heating mechanisms included in the transfer path in the pre-swapping. However, the present disclosure is not limited to this, and there may be a case where the unprocessed wafer is not heated by some of the plurality of heating mechanisms.

In the above disclosure, the description has been given with an example in which the processed wafer unloaded from the process chamber PM is cooled by all the cooling mechanisms included in the transfer path in the post-swapping. However, the present disclosure is not limited to this, and there may be a case where the processed wafer is not cooled by some of the plurality of cooling mechanisms.

In the above disclosure, a case where a TiN film is formed on a wafer by alternately supplying a titanium tetrachloride gas as a first process gas (first metal-containing gas, source gas) and a NH₃ gas as a second process gas (reactant gas) in the substrate processing, which is a manufacturing step of a semiconductor device, has been described as an example. However, the present disclosure is not limited to this. That is, the process gas used for the film forming is not limited to the titanium tetrachloride gas, the NH₃ gas, or the like, and another type of thin film may be formed using another type of gas. Furthermore, even in a case of using three or more types of process gases, the present disclosure can be applied as long as these process gases are alternately supplied to perform the film forming. Specifically, the first element may be not Ti but various elements such as Si, Zr, and Hf. The second element may be not N but 0, for example.

In the above disclosure, as the substrate processing, a case where a metal film is formed on a wafer surface has been mainly described as an example. However, the present disclosure is not limited to this. That is, the present disclosure can also be applied to film forming other than the thin film exemplified in the above-described disclosure, in addition to the thin film forming exemplified in the above-described disclosure. Regardless of the specific content of the substrate processing, the present disclosure can be applied not only to film forming but also to other substrate processing such as heating (annealing), plasma processing, diffusing, oxidizing, nitriding, and lithography.

According to the present disclosure, it is possible to further improve work efficiency in a substrate processing.

What is claimed is:

1. A substrate processing apparatus comprising:
a plurality of process chambers configured to process a substrate;
a plurality of standby chambers configured to accommodate the substrate;
a transfer chamber disposed adjacent to the plurality of standby chambers and the plurality of process chambers;
a transfer robot provided in the transfer chamber and configured to transfer a substrate between one of the plurality of process chambers and one of the plurality of standby chambers or between the plurality of standby chambers adjacent to each other across the transfer chamber;
a temperature adjustment mechanism configured to adjust temperature of at least one of the plurality of standby chambers; and
a controller configured to be capable of controlling the temperature adjustment mechanism so as to change a mode of temperature adjustment of the at least one of the plurality of standby chambers depending on a transfer path through which the substrate accommodated in the at least one of the plurality of standby chambers passes.

2. The substrate processing apparatus according to claim 1, wherein
the temperature adjustment mechanism includes a heating mechanism configured to heat the at least one of the plurality of standby chambers.

3. The substrate processing apparatus according to claim 1, wherein
the temperature adjustment mechanism includes a cooling mechanism configured to cool the at least one of the plurality of standby chambers.

4. The substrate processing apparatus according to claim 1, wherein
the controller controls the temperature adjustment mechanism such that unprocessed substrates to be processed in the plurality of process chambers are loaded into the plurality of process chambers simultaneously at a same temperature.

5. The substrate processing apparatus according to claim 1, wherein
the controller controls the temperature adjustment mechanism such that a plurality of processed substrates unloaded from the plurality of process chambers and loaded into one of the plurality of standby chambers are unloaded from the one of the standby chambers at a same temperature.

6. A method of manufacturing a semiconductor device, the method comprising:
by using a substrate processing apparatus including
a plurality of process chambers configured to process a substrate,
a plurality of standby chambers configured to accommodate the substrate,
a transfer chamber disposed adjacent to the plurality of standby chambers and the plurality of process chambers,
a transfer robot provided in the transfer chamber and configured to transfer a substrate, and
a temperature adjustment mechanism configured to adjust temperature of at least one of the plurality of standby chambers,
transferring the substrate between one of the plurality of process chambers and one of the plurality of standby chambers or between the plurality of standby chambers adjacent to each other across the transfer chamber by the transfer robot; and
performing processing of changing a mode of temperature adjustment on the substrate loaded into the at least one of the plurality of standby chambers depending on a transfer path through which the substrate accommodated in the at least one of the plurality of standby chambers passes.

7. The method according to claim 6, wherein
the temperature adjustment mechanism includes a heating mechanism configured to heat the at least one of the plurality of standby chambers, and, in performing the processing, performs processing of heating the substrate transferred to the at least one of the standby chambers.

8. The method according to claim 6, wherein
the temperature adjustment mechanism includes a cooling mechanism configured to cool the at least one of the plurality of standby chambers, and, in performing the processing, performs processing of cooling the substrate transferred to the at least one of the plurality of standby chambers.

9. The method according to claim 6, further comprising:
loading a plurality of unprocessed substrates to be processed in the plurality of process chambers into the plurality of process chambers simultaneously at a same temperature before performing processing of the plurality of unprocessed substrates in the plurality of process chambers.

10. The method according to claim 6, further comprising:
after processing a plurality of substrates in the plurality of process chambers, unloading the plurality of processed substrates unloaded from the plurality of process chambers and loaded into one of the plurality of standby chambers out from the one of the plurality of standby chambers at a same temperature.

11. A non-transitory computer-readable recording medium storing a program that causes, by a computer, a substrate processing apparatus to perform a process, the substrate processing apparatus including
a plurality of process chambers configured to process a substrate,
a plurality of standby chambers configured to accommodate the substrate,
a transfer chamber disposed adjacent to the plurality of standby chambers and the plurality of process chambers,
a transfer robot provided in the transfer chamber and configured to transfer the substrate, and
a temperature adjustment mechanism configured to adjust temperature of at least one of the plurality of standby chambers,
the process comprising:
transferring the substrate between one of the plurality of process chambers and one of the plurality of standby chambers or between the plurality of standby chambers adjacent to each other across the transfer chamber by the transfer robot; and
performing processing of changing a mode of temperature adjustment on the substrate loaded into the at least one of the plurality of standby chambers depending on a transfer path through which the substrate accommodated in the at least one of the plurality of standby chambers passes.

12. The non-transitory computer-readable recording medium according to claim 11, wherein
the temperature adjustment mechanism is a heating mechanism configured to heat the at least one of the plurality of standby chambers, and
in performing the processing, processing of heating the substrate transferred to the at least one of the plurality of standby chambers is performed.

13. The non-transitory computer-readable recording medium according to claim 11, wherein
the temperature adjustment mechanism is a cooling mechanism configured to cool the at least one of the plurality of standby chambers, and
in performing the processing, processing of cooling the substrate transferred to the at least one of the plurality of standby chambers is performed.

14. The non-transitory computer-readable recording medium according to claim 11, the process further comprising:
loading unprocessed substrates to be processed in the plurality of process chambers into the plurality of process chambers simultaneously at a same temperature before performing the processing.

15. The non-transitory computer-readable recording medium according to claim 11, the process further comprising:
unloading a plurality of processed substrates unloaded from the plurality of process chambers and loaded into one of the plurality of standby chambers out from the one of the plurality of standby chambers at a same temperature after performing the processing.
